(19) United States
(12) Patent Application Publication
(10) Pub. No.: US 2022/0077268 A1
(43) Pub. Date: Mar. 10, 2022

(54) DISPLAY SUBSTRATE, DISPLAY PANEL, AND ELECTRONIC DEVICE

(71) Applicant: BOE Technology Group Co., Ltd., Beijing (CN)

(72) Inventors: Libin Liu, Beijing (CN); Qian Yang, Beijing (CN)

(73) Assignee: BOE Technology Group Co., Ltd., Beijing (CN)

(21) Appl. No.: 17/417,460

(22) PCT Filed: Nov. 19, 2020
(86) PCT No.: PCT/CN2020/130091

§ 371 Date: Jun. 23, 2021

(30) Foreign Application Priority Data
Nov. 26, 2019 (CN) 201911180003.7

(51) Int. Cl. H01L 27/32

(52) U.S. Cl. CPC H01L 27/3272; H01L 27/124; H01L 27/3276; H01L 27/3262

(57) ABSTRACT

The present disclosure provides a display substrate, a display panel including the display substrate, and an electronic device. The display substrate includes: a base substrate; a transistor on the base substrate, wherein the transistor includes a first gate layer; a signal line located on the base substrate and configured to transmit an electrical signal; and a conductive isolation portion located between the transistor and the signal line adjacent to the transistor in a direction parallel to the base substrate, wherein the conductive isolation portion is electrically connected with a DC source signal on the display substrate.

### CROSS REFERENCE TO RELATED APPLICATION(S)

This application claims priority to the Chinese Patent Application No. 201911180003.7 filed on Nov. 26, 2019, the content of which is incorporated herein by reference in its entirety.

### TECHNICAL FIELD

The present disclosure relates to a field of display technology, and in particular to a display substrate, a display panel including the display substrate, and an electronic device including the display substrate or the display panel.

### BACKGROUND

OLED (Organic Light Emitting Diode) display panel is a very important type of display panel. It has advantages of a small weight, a small thickness and a high optical efficiency. In the OLED display panel, an existence of parasitic capacitance may cause mutual interference between adjacent circuit structures (especially various signal lines). With such mutual interference, a change in signals on some signal lines may affect parameters of other circuit structures, which may have an adverse effect on display.

### SUMMARY

The present disclosure provides a display substrate, including: a base substrate; a transistor on the base substrate, wherein the transistor includes a first gate layer; a signal line located on the base substrate and configured to transmit an electrical signal; and a conductive isolation portion located between the transistor and the signal line adjacent to the transistor in a direction parallel to the base substrate, wherein the conductive isolation portion is electrically connected with a DC source signal on the display substrate.

In some embodiments, a gate connection layer is further provided on the base substrate, the gate connection layer is electrically connected to the first gate layer, and the gate connection layer, the signal line and the conductive isolation portion are made of the same material and arranged in the same layer.

In some embodiments, the gate connection layer is located on a side of the first gate layer away from the base substrate, and an orthographic projection of the conductive isolation portion on the base substrate at least partially overlaps an orthographic projection of the first gate layer on the base substrate.

In some embodiments, a spacing area is provided between the conductive isolation portion and the signal line in the direction parallel to the base substrate, and the orthographic projection of the first gate layer on the base substrate does not overlap an orthographic projection of the spacing area on the base substrate.

In some embodiments, the gate connection layer is located on the side of the first gate layer away from the base substrate, and the orthographic projection of the conductive isolation portion on the base substrate does not overlap or at least partially overlaps the orthographic projection of the first gate layer on the base substrate.

In some embodiments, the display substrate further includes a second gate layer located between the first gate layer and the conductive isolation portion in a direction perpendicular to the base substrate, wherein the conductive isolation portion is located on the side of the first gate layer away from the base substrate.

In some embodiments, the orthographic projection of the conductive isolation portion on the base substrate at least partially overlaps an orthographic projection of the second gate layer on the base substrate.

In some embodiments, the display substrate further includes a first insulating layer located between the first gate layer and the second gate layer in the direction perpendicular to the base substrate and a second insulating layer located between the conductive isolation portion and the second gate layer in the direction perpendicular to the base substrate.

In some embodiments, the display substrate further includes a third insulating layer located between the base substrate and the first gate layer in the direction perpendicular to the base substrate.

In some embodiments, the transistor further includes an active layer located between the third insulating layer and the base substrate in the direction perpendicular to the base substrate, wherein an orthographic projection of the active layer on the base substrate at least partially overlaps the orthographic projection of the gate connection layer on the base substrate and the orthographic projection of the first gate layer on the base substrate.

In some embodiments, the DC source signal includes a circuit operating voltage source signal or a circuit common ground terminal voltage signal.

In some embodiments, the display substrate further includes a light emitting element, the light emitting element including an organic light emitting diode, wherein the transistor is a driving thin film transistor configured to drive the light emitting element to emit light.

In some embodiments, the orthographic projection of the conductive isolation portion on the base substrate includes a first extension portion extending in a first direction and a second extension portion extending in a second direction intersecting the first direction.

In some embodiments, the signal line is a data line.

The embodiments of the present disclosure further provide a display panel, including the display substrate according to any one of the embodiments described above.

The embodiments of the present disclosure further provide an electronic device, including the display substrate or the display panel according to any one of the embodiments described above.

### BRIEF DESCRIPTION OF THE DRAWINGS

In order to more clearly illustrate the technical solutions in the embodiments of the present disclosure or a related art, the drawings required in the description of the embodiments are briefly introduced below. Obviously, the drawings in the following description are some embodiments of the present disclosure. For those ordinary skilled in the art, other drawings may be obtained from these drawings without carrying out any inventive effort.

FIG. 1 shows a schematic diagram of an exemplary pixel driving circuit of an OLED display panel.

FIG. 2 schematically shows a partial film layer structure corresponding to a driving transistor T3 in the driving circuit in FIG. 1 and its surrounding circuits in a display substrate according to some embodiments of the present disclosure.

FIG. 3 schematically shows an exemplary cross-sectional view of the display substrate according to some embodiments of the present disclosure taken along line AX in FIG. 2.

FIG. 4 schematically shows a plan view of a display substrate without a conductive isolation portion corresponding to FIG. 2

FIG. 5 schematically shows an exemplary cross-sectional view of the display substrate taken along line BB′ in FIG. 4.

FIG. 6 schematically shows another exemplary cross-sectional view of the display substrate according to other embodiments of the present disclosure.

### DETAILED DESCRIPTION OF EMBODIMENTS

In order to make objectives, technical solutions and advantages of the present disclosure more apparent, the technical solutions of the present disclosure are clearly and completely described below with reference to the drawings of the embodiments of the present disclosure. Obviously, the embodiments described are only a part but not all of the embodiments of the present disclosure. Based on the embodiments of the present disclosure, all other embodiments obtained by those ordinary skilled in the art without carrying out inventive effort fall within the protection scope of the present disclosure. It should be noted that throughout the drawings, the same elements are represented by the same or similar reference numerals. In the following description, some specific embodiments are only used for descriptive purposes, and should not be construed as limiting the present disclosure. They are merely examples of the embodiments of the present disclosure. When it may cause confusion in the understanding of the present disclosure, conventional structures or configurations will be omitted. It should be noted that the shape and size of each component in the figure do not reflect the actual size and ratio, but merely illustrate the content of the embodiment of the present disclosure.

Unless otherwise defined, the technical or scientific terms used in the embodiments of the present disclosure should have the usual meanings understood by those skilled in the art. The words “first,” “second,” and the like used in the embodiments of the present disclosure do not indicate any order, quantity or importance, but are only used to distinguish different composition parts.

In addition, in the description of the embodiments of the present disclosure, the term “electrically connected” may mean that two components are electrically connected directly, or that two components are electrically connected via one or more other components. In addition, these two components may be electrically connected or coupled by wired or wireless means.

Transistors used in the embodiments of the present disclosure may all be thin film transistors or field effect transistors or other devices with the same characteristics. Since source and drain electrodes of the thin film transistor used here are symmetrical, the source and drain electrodes may be interchanged. In the following examples, the driving transistor is described as a P-type thin film transistor, and the other transistors are of the same or different type as or from the driving transistor according to the circuit design. Similarly, in other embodiments, the driving transistor may also be shown as an N-type thin film transistor.

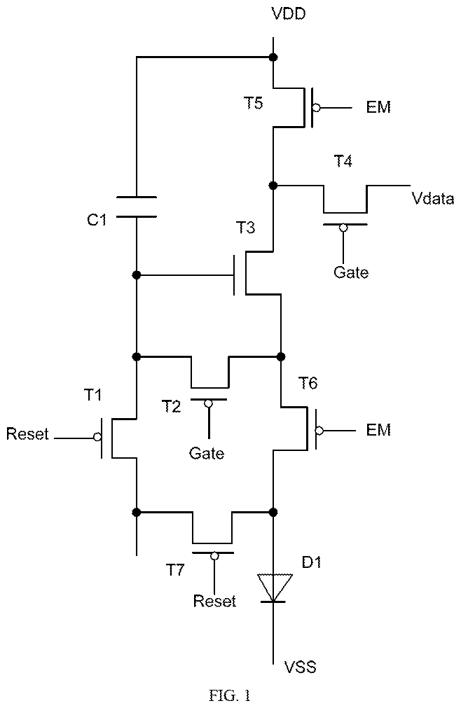

FIG. 1 shows a schematic diagram of an exemplary pixel driving circuit of an OLED display panel. The pixel driving circuit includes a first transistor T1, a second transistor T2, a third transistor T3, a fourth transistor T4, a fifth transistor T5, a sixth transistor T6, a seventh transistor T7, and a storage capacitor C1. Gate electrodes of the first transistor T1, the second transistor T2, the fourth transistor T4, the fifth transistor T5, the sixth transistor T6 and the seventh transistor T7 are respectively controlled by specific signals such as EM, Reset, Gate, and so on. The third transistor T3 is a driving transistor, which is used to mainly control a data voltage Vdata on the signal line to drive a light emitting element D1, such as an organic light emitting diode, to emit light. VDD and VSS signals are both DC voltage signals, which are used to provide necessary voltages for driving the light emitting element D1 to emit light.

The inventors of the present disclosure have discovered that, in the OLED display substrate, the data line is generally close to the driving thin film transistor used to drive the pixel unit to display images, so that the data line may cause interference (or crosstalk) to an adjacent driving thin film transistor. Specifically, in a light emission phase, a gate voltage of the driving thin film transistor (DTFT) is maintained only by the storage capacitor C1, and power may be redistributed after the signal on the data line jumps. According to the principle of conservation of charge, the gate voltage (Vg) of the DTFT is stabilized at a voltage value after the power is redistributed. This voltage value has a deviation of ΔVg from an initial value before the signal on the data line jumps, which may result in a change in the gate voltage of the DTFT. Such a change may cause a difference in display brightness of the display panel.

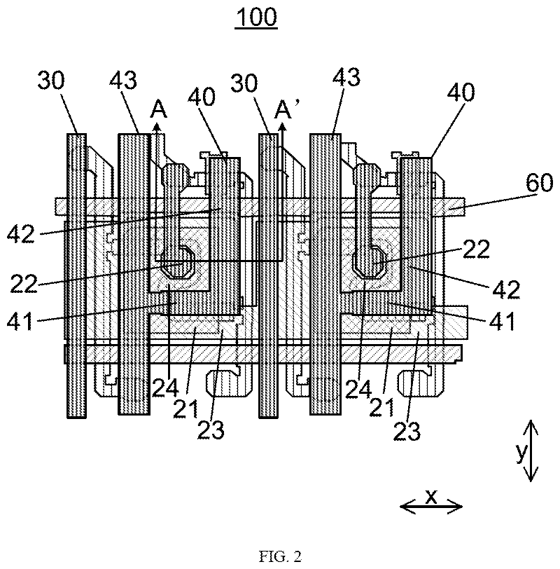

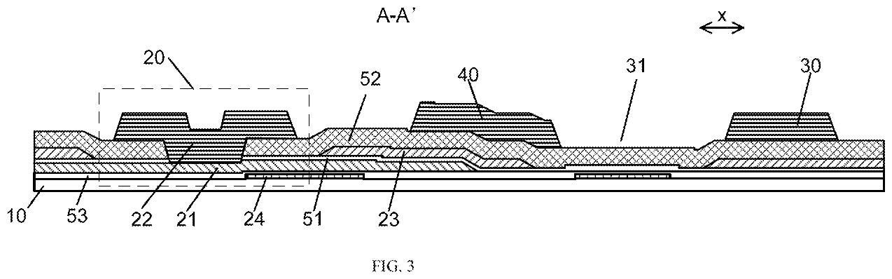

In order to solve the above problem, the embodiments of the present disclosure provide a display substrate 100. As shown in FIG. 2 and FIG. 3, the display substrate 100 includes a base substrate 10, a transistor 20 located on the base substrate 10, a signal line 30, and a conductive isolation portion 40. The transistor 20 includes a first gate layer 21. The signal line 30 may be located on the base substrate 10 and used for transmitting an electrical signal. The signal line 30 may be, for example, a data line for transmitting a data signal. The conductive isolation portion 40 is used to isolate an electric field between the signal line 30 and the first gate layer 21 of the transistor 20. The conductive isolation portion 40 may be located between the transistor 20 and the signal line 30 adjacent to the transistor 20 in a direction parallel to the base substrate 10 (for example, x-direction shown in FIG. 3). The conductive isolation portion 40 may be electrically connected to a DC source signal on the display substrate 100. Here, “the signal line adjacent to the transistor” does not mean that the transistor adjoins the signal line, but refers to the signal line close to the transistor (especially the signal line closest to the transistor), such as the data line of various data lines on the display substrate that is closest to the transistor.

In some embodiments, a gate connection layer 22 may be further provided on the base substrate 10. The gate connection layer 22 is electrically connected to the first gate layer 21. The gate connection layer 22, the signal line 30 and the conductive isolation portion 40 are made of the same material and arranged in the same layer. The gate connection layer 22 may be used to electrically connect the first gate layer 21 with wires or other circuit devices (such as other transistors). In some embodiments, the gate connection layer 22 may be made of the same material and arranged in the same layer as a source electrode and a drain electrode of the transistor 40. However, the embodiments of the present disclosure are not limited thereto, and the source electrode and the drain electrode of the transistor 40 may also be arranged, for example, in a different layer from the gate connection layer 22. For example, one or both of the source electrode and the drain electrode of the transistor 40 is arranged in the same layer as the active layer 24 of the transistor 40.

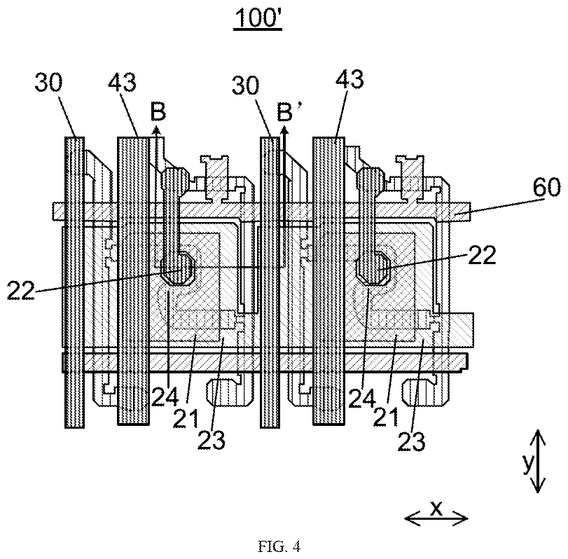

For clarity of the structure, FIG. 2 and FIG. 4 only show a structure of a conductive layer, and a structure of the insulating layer is not shown. In FIG. 2 and FIG. 4, in addition to the data line, the transistor and the conductive isolation portion, conventional structures necessary for the display substrate such as a gate line 60 is also shown.

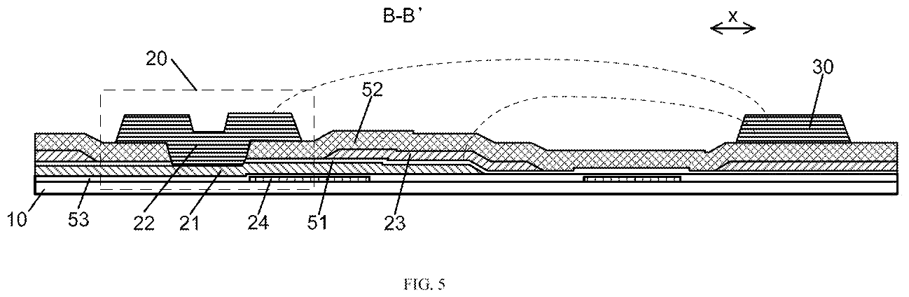

In order to explain a function of the conductive isolation portion 40 more clearly, the present disclosure provides a structure of a display substrate 100′ shown in FIG. 4 and FIG. 5 that corresponds to the display substrate 100 shown in FIG. 2 and FIG. 3. A difference between the display substrate 100′ shown in FIG. 4 and FIG. 5 and the display substrate 100 shown in FIG. 2 and FIG. 3 is that the display substrate 100′ shown in FIG. 4 and FIG. 5 does not include the conductive isolation portion 40, while the display substrate 100 shown in FIG. 2 and FIG. 3 includes the conductive isolation portion 40. As shown in FIG. 5, in a case that the display substrate 100′ does not include the conductive isolation portion 40, an electric field exists between the signal line 30 and the gate connection layer 22 and between the signal line 30 and the first gate layer 21 (indicated by a dotted line shown in FIG. 5). Since the gate connection layer 22 is electrically connected to the first gate layer 21, the electric field between the signal line 30 and the first gate layer 21 and the electric field between the signal line 30 and the gate connection layer 22 may affect the gate voltage of the first gate layer 21 of the transistor 20. When data is loaded on the signal line 30, the electric field between the signal line 30 and the first gate layer 21 may vary with a change of the voltage on the signal line 30. This may cause a certain change in the gate voltage of the first gate layer 21 of the transistor 20, which results in interference to an operation of the transistor 20. If the transistor 20 is a driving transistor for driving display pixels to operate, such a change in the gate voltage may cause uneven display brightness.

After the conductive isolation portion 40 is provided, as shown in FIG. 3, the conductive isolation portion 40 may isolate the electric field of the signal line 30 from the gate connection layer 22 and the first gate layer 21, and also reduce a parasitic capacitance between the signal line 30 and the first gate layer 21. In this way, a coupling effect between the first gate layer 21 and the signal line 30 may be weakened. An amount of the change in the gate voltage of the transistor 20 with the voltage on the signal line 30 may become smaller, so that the difference in the display brightness may be reduced. Because the conductive isolation portion 40 is electrically connected to the DC source signal on the display substrate 100, it has a relatively fixed potential, which does not change with the voltage of the signal line 30 and has very little effect on the gate voltage of the first gate layer 21 of the transistor 20. In this way, the first gate layer 21 may be shielded, so that the gate voltage of the transistor 20 is not interfered by the change of the voltage on the signal line 30.

This design does not increase a complexity of the display substrate manufacturing process and mask manufacturing, may lessen a longitudinal crosstalk on the display substrate (interference on the transistor from the adjacent signal line, such as the data line), and is especially suitable for a flexible display that does not require a high resolution.

In some embodiments, the gate connection layer 22, the signal line 30 and the conductive isolation portion 40 may be made of the same material and arranged in the same layer. On the one hand, the manufacturing process may be simplified. On the other hand, since a conductive layer where the gate connection layer 22 and the signal line 30 are located usually has a large thickness, for example, a thickness of 7500 angstroms, the signal line 30 may be better isolated from the gate connection layer 22 and the first gate layer 21 of the transistor 20. Therefore, arranging the conductive isolation portion 40 in the same layer as the gate connection layer 22 and the signal line 30 is beneficial to ensure the thickness of the conductive isolation portion 40 so as to better resist the interference.

In some embodiments, as shown in FIG. 3, the gate connection layer 22 may be located on a side (an upper side in FIG. 3) of the first gate layer 21 away from the base substrate 10. This is beneficial for the shielding of the first gate layer 21 by the conductive isolation portion 40. An orthographic projection of the conductive isolation portion 40 on the base substrate 10 at least partially overlaps an orthographic projection of the first gate layer 21 on the base substrate 10. The overlap of the orthographic projection of the conductive isolation portion 40 on the base substrate 10 and the orthographic projection of the first gate layer 21 on the base substrate 10 is beneficial for the isolation between the signal line 30 and the first gate layer 21 by the conductive isolation section 40.

In some embodiments, a spacing area 31 is provided between the conductive isolation portion 40 and the signal line 30 in the direction parallel to the base substrate (for example, the x-direction), and the orthographic projection of the first gate layer 21 on the base substrate 10 does not overlap an orthographic projection of the spacing area 31 on the base substrate 10. As shown in FIG. 3, the orthographic projection of the first gate layer 21 on the base substrate 10 does not overlap the orthographic projection of the spacing area 31 on the base substrate 10, which means that the first gate layer 21 does not extend beyond the conductive isolation portion 40. This is also advantageous for the isolation of the conductive isolation portion 40 between the signal line 30 and the first gate layer 21. However, it should be noted that the embodiments of the present disclosure are not limited to the case that the orthographic projection of the first gate layer 21 on the base substrate 10 does not overlap the orthographic projection of the spacing area 31 on the substrate 10 at all. For example, if the first gate layer 21 extends beyond the conductive isolation portion 40, but the conductive isolation portion 40 may still play a role in weakening the influence of the electric field of the signal line 30 on the first gate layer 21, a desired function may also be achieved.

In some embodiments, the orthographic projection of the first gate layer 21 on the substrate 10 may not overlap the orthographic projection of the spacing area 31 on the substrate 10, and the orthographic projection of the conductive isolation portion 40 on the base substrate 10 may not overlap or at least partially overlaps the orthographic projection of the first gate layer 21 on the base substrate 10.

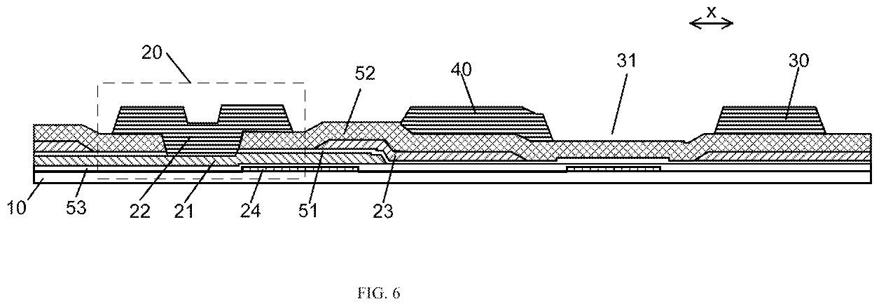

FIG. 6 schematically shows a variation of the display substrate according to other embodiments of the present disclosure. A difference between the embodiment shown in FIG. 6 and the embodiment shown in FIG. 3 is that the orthographic projection of the conductive isolation portion 40 on the base substrate 10 does not overlap the orthographic projection of the first gate layer 21 on the base substrate 10. That is, in the direction parallel to the base substrate 10 (for example, the x-direction shown), the first gate layer 21 is completely located on a side of the conductive isolation portion 40 away from the signal line 30. This may also enable the conductive isolation portion 40 to isolate the signal line 30 from the first gate layer 21.

In some embodiments, the display substrate may further includes a second gate layer 23 located between the first gate layer 21 and the conductive isolation portion 40 in a direction perpendicular to the base substrate. The conductive isolation portion 40 may be located on a side of the first gate layer 21 away from the base substrate 10. This is also advantageous for the conductive isolation portion 40 to isolate the first gate layer 21 from the signal line 30. In the embodiments of the present disclosure, the first gate layer 21 may be used, for example, to form the gate electrode of the transistor on the display substrate, and the second gate layer 23 may be used, for example, to form the storage capacitor on the display substrate, such as the storage capacitor C1 shown in FIG. 1. The first gate layer 21 and the second gate layer 23 may be separated by an insulating layer.

In some embodiments, the orthographic projection of the conductive isolation portion 40 on the base substrate 10 at least partially overlaps an orthographic projection of the second gate layer 23 on the base substrate 10.

In some embodiments, as shown in FIG. 3, the display substrate may further include a first insulating layer 51 and a second insulating layer 52. The first insulating layer 51, for example, a second gate insulating layer (which may be made of a material such as silicon oxide), may be located between the first gate layer 21 and the second gate layer 23 in the direction perpendicular to the base substrate. The second insulating layer 52, for example, an intermediate dielectric layer, may be located between the conductive isolation portion 40 and the second gate layer 23 in the direction perpendicular to the base substrate. In some embodiments, the display substrate 100 may further include a third insulating layer 53, for example, a first gate insulating layer (which may be made of a material such as silicon oxide), located between the base substrate 10 and the first gate layer 21 in the direction perpendicular to the base substrate. The transistor 20 may further include an active layer 24 that may be located between the third insulating layer 53 and the base substrate 10 in the direction perpendicular to the base substrate. An orthographic projection of the active layer 24 on the base substrate 10 at least partially overlaps each of the orthographic projection of the gate connection layer 22 on the base substrate 10 and the orthographic projection of the first gate layer 21 on the base substrate 10. This may ensure a normal realization of the function of the transistor 20.

In the embodiments of the present disclosure, the DC source signal electrically connected with the conductive isolation portion 40 may include, for example, a circuit operating voltage source signal (VDD) or a circuit common ground terminal voltage signal (VSS). For example, a suitable DC source signal to be electrically connected with the conductive isolation portion 40 may be selected according to an arrangement position of the circuit operating voltage source signal and the circuit common ground terminal voltage signal. For example, in the embodiment of FIG. 2, the conductive isolation portion 40 is electrically connected to a VDD signal line 43, and the conductive isolation portion 40 may also be regarded as a part of the VDD signal line 43.

In the embodiments of the present disclosure, the display substrate may include a light emitting element D1 such as an organic light emitting diode. As an example, the transistor 20 may be a driving thin film transistor for driving the light emitting element D1 to emit light.

In some embodiments, the conductive isolation portion 40 may be an isolation line. For example, as shown in FIG. 2, the orthographic projection of the conductive isolation portion 40 on the base substrate 10 includes a first extension portion 41 extending in a first direction (for example, the x-direction shown in FIG. 2) and a second extension portion 42 extending in a second direction (for example, y-direction shown in FIG. 2). In some embodiments, the first direction is substantially perpendicular to the second direction. However, the embodiments of the present disclosure are not limited to the case that an extension direction of the first extension portion 41 is perpendicular to an extension direction of the second extension portion 42. For example, the extension direction of the first extension portion 41 and the extension direction of the second extension portion 42 may be inclined to each other. In other words, the first direction and the second direction may cross each other. In some embodiments, the conductive isolation portion 40 may include only the second extension portion 42 but not include the first extension portion 41. In the embodiments of the present disclosure, a specific shape of the conductive isolation portion 40 is not limited, as long as the interference of the signal line 30 to the gate connection layer 22 and the first gate layer 21 of the transistor 20 may be weakened. The conductive isolation portion 40 may further isolate the signal line 30 from the gate connection layer 22 and the first gate layer 21 of the transistor 20 on more than one side or more than two sides of the transistor 20.

The embodiments of the present disclosure further provide a display panel, including the display substrate 100 as described in any one of the embodiments described above. Although the OLED display substrate is illustrated by way of example in describing the embodiments of the present disclosure, those skilled in the art should understand that the embodiments of the present disclosure are not limited thereto. For example, a technical concept of the present disclosure may also be used for other types of display panels.

The embodiments of the present disclosure further provide an electronic device, which may include the display substrate or the display panel according to any one of the embodiments described above. The electronic device in the embodiments of the present disclosure may be any product or component with a display function, such as electronic paper, a mobile phone, a tablet computer, a television, a notebook computer, a digital photo frame, a navigator, and so on.

Unless there are technical obstacles or contradictions, the various embodiments of the present disclosure described above may be freely combined to form additional embodiments, and these additional embodiments are all within the protection scope of the present disclosure.

Although the present disclosure is described with reference to the drawings, the embodiments disclosed in the drawings are for illustrative purposes only and are not to be construed as limiting the present disclosure.

Although the present disclosure has been described with reference to several typical embodiments, it should be understood that the terms used are illustrative and exemplary rather than restrictive. Since the present disclosure may be implemented in various forms without departing from the spirit or essence of the present disclosure, it should be understood that the embodiments described above are not limited to any of the foregoing details, but should be interpreted broadly within the spirit and scope defined by the appended claims. Therefore, all changes and modifications falling within the scope of the claims or their equivalents shall be covered by the appended claims.

1. A display substrate, comprising:
a base substrate;
a transistor on the base substrate, wherein the transistor comprises a first gate layer;
a signal line located on the base substrate and configured to transmit an electrical signal; and
a conductive isolation portion located between the transistor and the signal line adjacent to the transistor in a direction parallel to the base substrate,
wherein the conductive isolation portion is electrically connected with a DC source signal on the display substrate.

2. The display substrate of claim 1, wherein a gate connection layer is further provided on the base substrate, the gate connection layer is electrically connected to the first gate layer, and the gate connection layer, the signal line and the conductive isolation portion are made of the same material and arranged in the same layer.

3. The display substrate of claim 2, wherein the gate connection layer is located on a side of the first gate layer away from the base substrate, and an orthographic projection of the conductive isolation portion on the base substrate at least partially overlaps an orthographic projection of the first gate layer on the base substrate.

4. The display substrate of claim 2, wherein a spacing area is provided between the conductive isolation portion and the signal line in the direction parallel to the base substrate, and the orthographic projection of the first gate layer on the base substrate does not overlap an orthographic projection of the spacing area on the base substrate.

5. The display substrate of claim 4, wherein the gate connection layer is located on a side of the first gate layer away from the base substrate, and an orthographic projection of the conductive isolation portion on the base substrate does not overlap the orthographic projection of the first gate layer on the base substrate.

6. The display substrate of claim 4, wherein the gate connection layer is located on a side of the first gate layer away from the base substrate, and an orthographic projection of the conductive isolation portion on the base substrate at least partially overlaps an orthographic projection of the first gate layer on the base substrate.

7. The display substrate of claim 1, further comprising: a second gate layer located between the first gate layer and the conductive isolation portion in a direction perpendicular to the base substrate, wherein the conductive isolation portion is located on a side of the first gate layer away from the base substrate.

8. The display substrate of claim 7, wherein an orthographic projection of the conductive isolation portion on the base substrate at least partially overlaps an orthographic projection of the second gate layer on the base substrate.

9. The display substrate of claim 8, further comprising: a first insulating layer located between the first gate layer and the second gate layer in the direction perpendicular to the base substrate; and a second insulating layer located between the conductive isolation portion and the second gate layer in the direction perpendicular to the base substrate.

10. The display substrate of claim 2, further comprising a third insulating layer located between the base substrate and the first gate layer in the direction perpendicular to the base substrate.

11. The display substrate of claim 10, wherein the transistor further comprises an active layer located between the third insulating layer and the base substrate in the direction perpendicular to the base substrate, and an orthographic projection of the active layer on the base substrate at least partially overlaps each of an orthographic projection of the gate connection layer on the base substrate and an orthographic projection of the first gate layer on the base substrate.

12. The display substrate of claim 1, wherein the DC source signal comprises a circuit operating voltage source signal.

13. The display substrate of claim 1, wherein the DC source signal comprises a circuit common ground terminal voltage signal.

14. The display substrate of claim 1, further comprising a light emitting element, the light emitting element comprising an organic light emitting diode, wherein the transistor is a driving thin film transistor configured to drive the light emitting element to emit light.

15. The display substrate of claim 1, wherein an orthographic projection of the conductive isolation portion on the base substrate comprises a first extension portion extending in a first direction and a second extension portion extending in a second direction, and the second direction intersects the first direction.

16. The display substrate of claim 1, wherein the signal line is a data line.

17. A display panel comprising the display substrate of claim 1.

18. An electronic device comprising the display substrate of claim 1.
